(19) United States
(12) Patent Application Publication
(10) Pub. No.: US 2010/0218804 A1
(43) Pub. Date: Sep. 2, 2010

(54) Method for aligning a lens array to a cell array

(75) Inventors: Hwa-Yuh Shin, Longtan Shiang (TW); Hung-Zen Kuo, Longtan Shiang (TW); Hung-Sheng Chiu, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 11/987,401

(22) Filed: Nov. 29, 2007

(51) Int. Cl. H01L 31/052; H01L 31/0232

(52) U.S. Cl. 136/246; 257/E31.127; 257/E31.001

(57) ABSTRACT

A concentration photovoltaic module includes a lens array and a cell array. The lens array includes lenses and alignment windows. The cell array includes solar cells and alignment points. A method is provided for aligning the lens array to the cell array. In the method, a collimation module is made with collimated light sources. The concentration photovoltaic module is located under the collimation module so that the alignment windows are located under the collimated light sources. The collimated light sources are used to turn sunlit into collimated light beams and cast the collimated light beams onto the cell array through the alignment windows. The lens array is moved relative to the cell array so that the collimated light beams are directed to the alignment points. Hence, light beams emitted from the lenses are directed to the solar cells.

### BACKGROUND OF INVENTION

1. Field of Invention

The present invention relates to a concentration photovoltaic module and, more particularly, to a method for aligning a lens array to a cell array of a concentration photovoltaic module.

2. Related Prior Art

A concentration photovoltaic module includes lenses to focus sunlit onto solar cells that are made of a small area and a high photoelectric conversion coefficient. Because the sunlit is concentrated into light beams, only a small amount of solar cells are needed for generating a considerable amount of electricity. Therefore, the concentration photovoltaic module can efficiently generate electricity at a low cost.

Generally, the alignment of the lenses of the concentration photovoltaic module to the solar cells are dependent on a spot-type light source. The sun is an appropriate spot-type light source. However, the intensity of the sunlit and the weather are not under our control. The alignment of the lenses to the lenses is often affected by the weather and cannot be done smoothly.

The present invention is therefore intended to obviate or at least alleviate the problems encountered in prior art.

### SUMMARY OF INVENTION

It is the primary objective of the present invention to provide a method for aligning a lens array to a cell array of a concentration photovoltaic module.

To achieve the foregoing objective, the lens array is made with lenses and alignment windows while the cell array is made with solar cells and alignment points. A collimation module is made with collimated light sources. The concentration photovoltaic module is located under the collimation module so that the alignment windows are located under the collimated light sources. The collimated light sources are used to turn sunlit into collimated light beams and cast the collimated light beams onto the cell array through the alignment windows. The lens array is moved relative to the cell array so that the collimated light beams are directed to the alignment points. Hence, light beams emitted from the lenses are directed to the solar cells.

Other objectives, advantages and features of the present invention will become apparent from the following description referring to the attached drawings.

### BRIEF DESCRIPTION OF DRAWINGS

The present invention will be described via detailed illustration of the preferred embodiment referring to the drawings.

FIG. 1 is a flowchart of a method for aligning a lens array to a cell array according to the preferred embodiment of the present invention.

FIG. 2 is a top view of a collimation module for use in the method shown in FIG. 1.

FIG. 3 is a top view of a lens array for use in the method shown in FIG. 1.

FIG. 4 is a top view of a cell array for use in the method shown in FIG. 1.

FIG. 5 is an exploded view of the collimation module shown in FIG. 2 and a concentration photovoltaic module including the lenses shown in FIG. 3 and the solar cells shown in FIG. 4.

FIG. 6 shows the operation of aligning the lens array to the cell array shown in FIG. 5.

### DETAILED DESCRIPTION OF PREFERRED EMBODIMENT

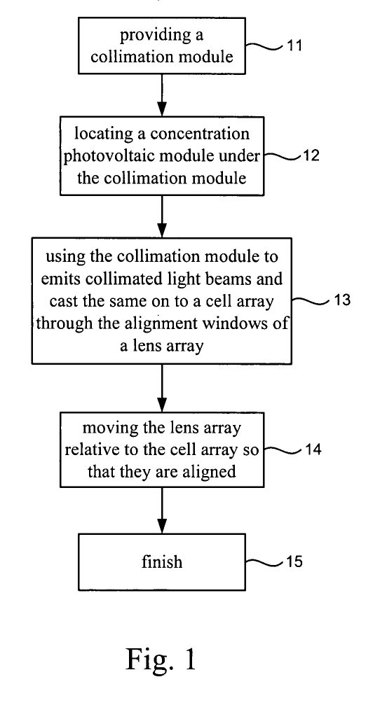

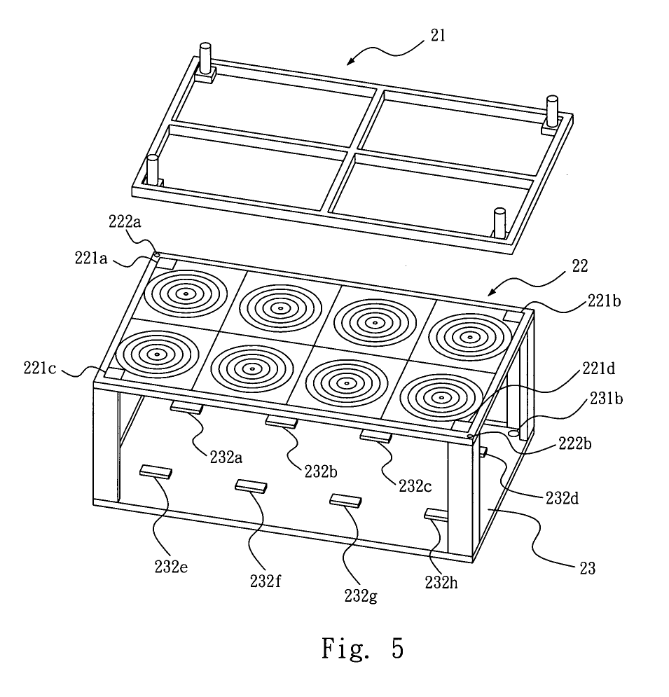

Referring to FIG. 1, there is shown a method for aligning a lens array 22 to a cell array 23 of a concentration photovoltaic module 1 (FIG. 5).

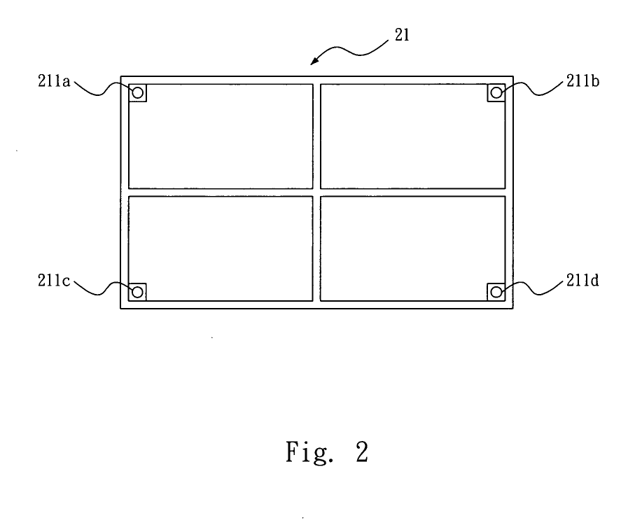

Referring to FIGS. 1 and 2, at 11, a collimation module 21 is provided. The collimation unit 2 includes a plurality of collimated light sources 211a, 211b, 221c and 211d.

Referring to FIGS. 1 and 5, at 12, the concentration photovoltaic module 1 is located under the collimation unit 21.

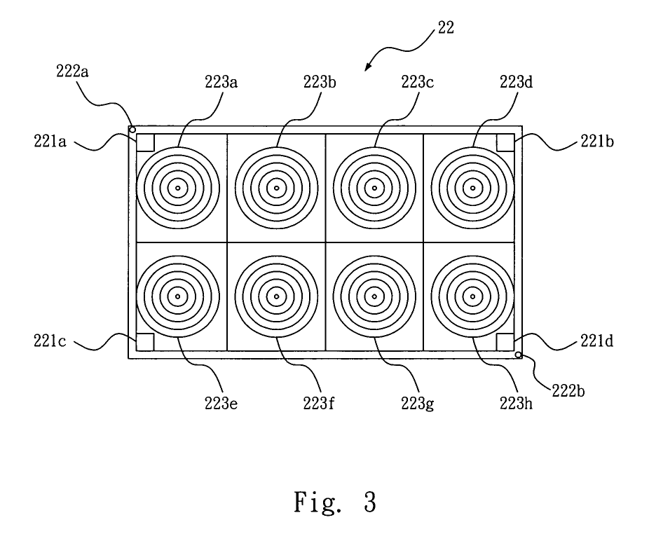

Referring to FIG. 3, the lens array 22 includes a plurality of alignment windows 221a, 221b, 221c and 221d, a plurality of alignment apertures 222a and 222b and a plurality of concentration lenses 223a, 223b, 223c, 223d, 223e, 223f, 223g and 223h. The lens array 22 is attached to the bottom of the collimation module 21 so that they are movable together and that the alignment windows 221a to 221d are aligned to the collimated light sources 211a to 211d.

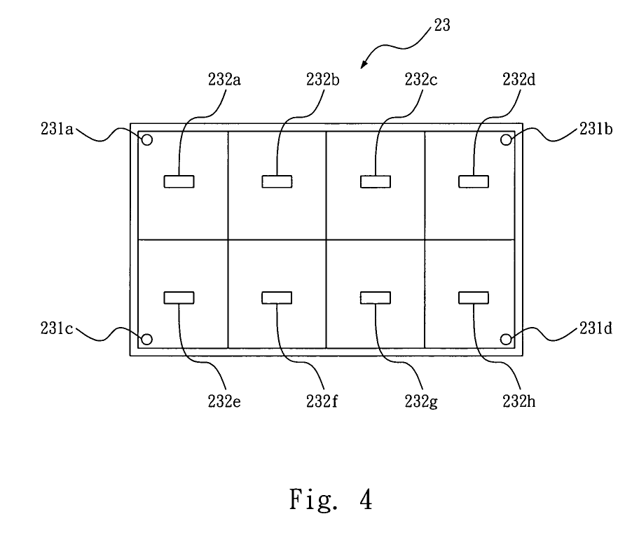

Referring to FIG. 4, the cell array 23 includes a plurality of alignment points 231a, 231b, 231c and 231d and a plurality of solar cells 232a, 232b, 232c, 232d, 232e, 232f, 232g and 232h. The alignment points 231a to 231d are located near the corners of the cell array 23. The cell array 23 is located under the lens array 22 so that the alignment points 231a to 231d are located under the alignment windows 221a to 221d and that they are movable together with each other.

At 13, the collimation module 21 collimates sunlit and emits collimated light beams 2a, 2b, 2c and 2d. The collimated light beams 2a to 2d are preferably laser. The collimated light beams 2a to 2d are cast onto the cell array 23 through the alignment windows 221a to 221d of the lens array 22.

At 14, the lens array 22 is horizontally moved relative to the cell array 23, i.e., the lens array 22 or the cell array 23 is horizontally moved, so that the collimated light beams 2a to 2d are cast on the alignment points 231a to 231d through the alignment windows 221a to 221d.

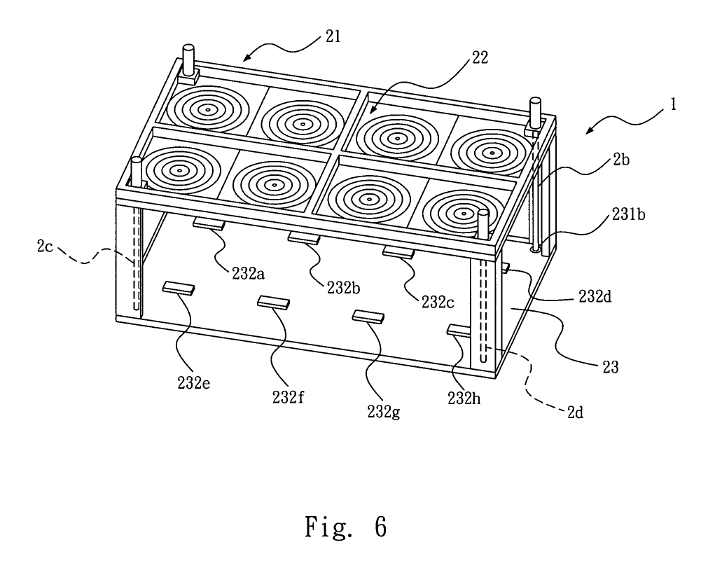

Referring to FIGS. 1 and 6, at 15, the collimation module 21 collimates the sunlit and casts the collimated light on the lens array 22. The concentration lenses 223a to 223h of the lens array 22 concentrate the collimated light into a plurality of light spots and cast the light spots on the solar cells 232a to 232h of the cell array 23.

As discussed above, optical alignment is used in the present invention. to FIGS. 1 and 2, at 11, the collimation module 21 is provided. The collimated light sources 211a, 211b, 221c and 211d of the collimation unit 2 cast collimated light beams 2a to 2d onto the alignment points 231a to 231d of the cell array 23 through the alignment windows 221a to 221d of the lens array 22. The lens array 22 or the cell array 23 is moved so that the alignment windows 221a to 221d are aligned to the alignment points 231a to 231d. Therefore, the axes of the light beams emitted from the concentration lenses 223a to 223h of the lens array 22 are aligned to the centers of the solar cells 232a to 232h of the cell array 23.

The optical alignment is conducted without having to complicate the structure of the concentration photovoltaic module 1. Therefore, the method according to the present invention enables the concentration photovoltaic module 1 to efficiently generates electricity at a low cost.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A method for aligning a lens array to a cell array of a concentration photovoltaic module, wherein the lens array comprises lenses and alignment windows, the cell array comprises solar cells and alignment points, and the method comprises the steps of:
providing at least one collimation module comprising collimated light sources;
locating the concentration photovoltaic module under the collimation module so that the alignment windows are located under the collimated light sources;
using the collimated light sources to turn sunlit into collimated light beams and cast the collimated light beams onto the cell array through the alignment windows; and
adjusting the relative position between the lens array and the cell array so that the collimated light beams are directed to the alignment points and that light beams emitted from the lenses are directed to the solar cells.

2. The apparatus according to claim 1, wherein the lens array comprises a plurality of alignment apertures.

3. The apparatus according to claim 1, wherein the alignment points are located near the corners of the cell array.

4. The apparatus according to claim 1, wherein the collimated light sources emit laser.
